(19) United States
(12) Patent Application Publication
(10) Pub. No.: US 2025/0383087 A1
(43) Pub. Date: Dec. 18, 2025

(54) LOW GAS PRESSURE DETECTION AND COMPENSATION OPERATION METHOD OF GAS WATER HEATER

(71) Applicant: Jin Min CHOI, Seoul (KR)

(72) Inventor: Jin Min CHOI, Seoul (KR)

(21) Appl. No.: 19/227,829

(22) Filed: Jun. 4, 2025

(30) Foreign Application Priority Data
Jun. 18, 2024 (KR) 10-2024-0078874

(51) Int. Cl. F23N 3/08; F23N 5/00; F24H 1/00; F24H 15/35; F24H 15/36; G01K 3/00; G01R 19/00

(52) U.S. Cl. CPC F23N 3/082; F23N 5/003; F24H 1/0036; F24H 15/35; F24H 15/36; G01K 3/005; G01R 19/0038; F23N 2225/16; F23N 2229/22; F23N 2233/08; F23N 2900/05001

(57) ABSTRACT

A low gas pressure detection and compensation operation method of a gas water heater according to a preferred embodiment of the present disclosure includes an output calculation step of calculating combustion output through combustion temperature detected by a temperature sensor and comparing the calculated output with a reference output, a flame voltage comparison step of detecting flame voltage and comparing the detected flame voltage with a reference flame voltage when the calculated output is smaller than the reference output, and a correction step of adjusting a supply air amount when the detected flame voltage is smaller than the reference flame voltage.

### CROSS-REFERENCE TO RELATED APPLICATION

This application claims the benefit of and priority to Korean Patent Application No. 10-2024-0078874, filed on Jun. 18, 2024, the entire disclosure(s) of which is hereby incorporated herein by reference in its entirety.

### TECHNICAL FIELD

The present disclosure relates to a low gas pressure detection and compensation operation method, and more specifically, to a low gas pressure detection and compensation operation method of a gas water heater, which detects low gas pressure by checking the level of flame voltage together with output, and then operates at an appropriate air ratio by correcting the RPM of a blower after checking the low gas pressure.

### BACKGROUND

In general, when many products burn at the same time using gas, the pressure of the gas supplied to each product becomes a reference value or less (low gas pressure), which may result in failure to ignite or an increase in CO due to an improper air ratio.

For example, in a case where supplying fuel gas to multiple households to operate gas water heaters or gas boilers, or the like, when multiple households use gas water heaters or gas boilers at the same time, the pressure of the gas supplied to each household may decrease as described above.

At this time, since various gas products cannot make judgments about gas pressure changes, it is difficult to effectively respond to the phenomenon of a flame going out during combustion or CO exceeding the reference value due to deviation from the proper air ratio. In particular, since the gas products operate smoothly again when the gas concentration phenomenon is resolved, efforts to find a solution to the problem are bound to be weak.

Among existing products, there are examples of checking low gas pressure conditions by calculating output through a temperature sensor, but the possibility of error is very high because the composite error rate of the temperature sensor can be up to 30%. In addition, since the flame detection method in existing products is determined only as on/off, the exact flame status cannot be determined, even when there is a change in the air ratio.

FIG. 1 is a graph illustrating the change in a calculated output and an air ratio according to the increase in RPM during normal gas pressure operation, and FIG. 2 is a graph illustrating the change in a calculated output and an air ratio according to the increase in RPM during low gas pressure operation.

As illustrated in FIG. 1, when the RPM of the blower increases during normal gas pressure operation, the calculated output increases. Meanwhile, the mixing ratio of air included in the mixed gas can be maintained constant.

As illustrated in FIG. 2, even when the RPM of the blower increases during low gas pressure operation, the calculated output does not increase proportionally, but rather a rise rate of the calculated output decreases. Meanwhile, the air ratio does not remain constant from the low gas pressure operation but increases. In this case, CO generation may increase and the possibility of misfire may increase.

### SUMMARY

The present disclosure has been made to solve the problems of the related art as described above, and an object of the present disclosure is to provide a low gas pressure detection and compensation operation method of a gas water heater, which can easily and precisely determine changes in gas pressure, stably maintain an air ratio according to changes in gas pressure, and accurately determine a flame state.

In order to achieve the above-described object, there is provided a low gas pressure detection and compensation operation method of a gas water heater according to a preferred embodiment of the present disclosure, the method including: an output calculation step of calculating combustion output through combustion temperature detected by a temperature sensor and comparing the calculated output with a reference output; a flame voltage comparison step of detecting flame voltage and comparing the detected flame voltage with a reference flame voltage when the calculated output is smaller than the reference output; and a correction step of adjusting a supply air amount when the detected flame voltage is smaller than the reference flame voltage.

It is determined that a supply gas pressure is in a low gas pressure state smaller than a reference value when the calculated output is smaller than the reference output and a current flame voltage is smaller than the reference flame voltage.

When the supply gas pressure is determined to be in the low gas pressure state, in the correction step, the supply air amount may be adjusted by adjusting rpm of a blower to maintain an air ratio (actual air value/theoretical air value) within a normal range.

An alarm may be displayed to a user when the supply gas is in the low gas pressure state.

A temperature sensor measurement value, a flame detection voltage, the RPM of the blower, wind pressure information of the blower, and an amount of carbon monoxide (CO) generated may be considered in a process of checking the low gas pressure state of the supply gas and controlling the supply air amount.

An operation may be terminated normally after high-heat combustion continues for a predetermined period of time when the output calculated in the output calculation step is determined to be normal.

An operation may be normally terminated after high-heat combustion continues for a predetermined period of time when it is determined that there is no decrease in flame voltage. In the correction step, the RPM of the blower may be lowered to reduce the amount of air supplied, thereby maintaining the air ratio within a normal range.

A maximum RPM of the blower may be corrected in the correction step.

When the RPM of the blower is corrected in the correction step, the RPM of the blower may decrease and then remain constant, the air ratio may be kept constant at a normal value, the output may be also kept constant, and the flame voltage may also rebound and increase at an RPM correction point and then remain constant.

The output may be calculated in real time in the output calculation step.

### Advantageous Effects

According to the low gas pressure detection and compensation operation method of the gas water heater of the present disclosure, the flame can be prevented from going out even at low gas pressure, a stable air ratio can be maintained, CO generation can be suppressed, and a gas alarm can be displayed to the consumer, thereby supplementing problems such as piping, thereby preventing accidents.

In particular, according to the present disclosure, since the state of the flame is determined by the voltage change, the change in the air ratio can be easily observed by the voltage fluctuation according to the flame state, so an appropriate air ratio can be stably maintained.

In addition, according to the present disclosure, by simultaneously observing the output calculation based on data detected by the temperature sensor and the decrease in flame voltage, the determination error when determining the low gas pressure is minimized, so that an appropriate air ratio can be stably maintained.

### BRIEF DESCRIPTION OF THE DRAWINGS

FIG. 1 is a graph illustrating change in calculated output and air ratio according to the increase in RPM during a normal gas pressure operation.

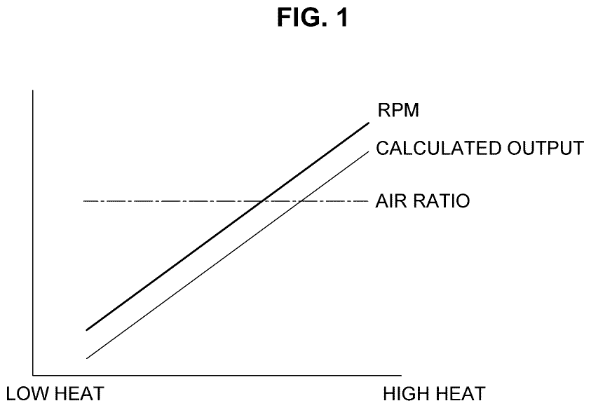

FIG. 2 is a graph illustrating the change in calculated output and air ratio according to the increase in RPM during a low gas pressure operation.

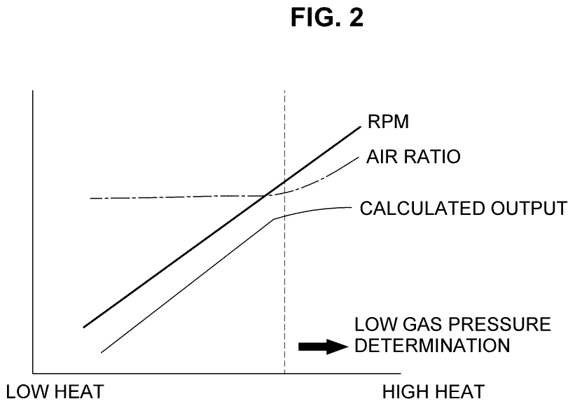

FIG. 3 is a process diagram illustrating a process of controlling operation according to a low gas pressure detection and compensation operation method of a gas water heater according to one embodiment of the present disclosure.

FIG. 4 is a flowchart illustrating a process for controlling operation according to the low gas pressure detection and compensation operation method of a gas water heater according to one embodiment of the present disclosure.

FIG. 5 is a graph illustrating operation according to the low gas pressure detection and compensation operation method of a gas water heater according to one embodiment of the present disclosure when a low gas pressure condition occurs after boiler operation.

FIG. 6 is a graph comparing a flame detection method applied to the low gas pressure detection and compensation operation method of a gas water heater according to one embodiment of the present disclosure with a conventional flame detection method.

FIG. 7 is a table illustrating an example of operation under normal gas pressure and low gas pressure conditions.

### DETAILED DESCRIPTION

Hereinafter, a low gas pressure detection and compensation operation method of a gas water heater according to a preferred embodiment of the present disclosure will be described in detail with reference to the attached drawings.

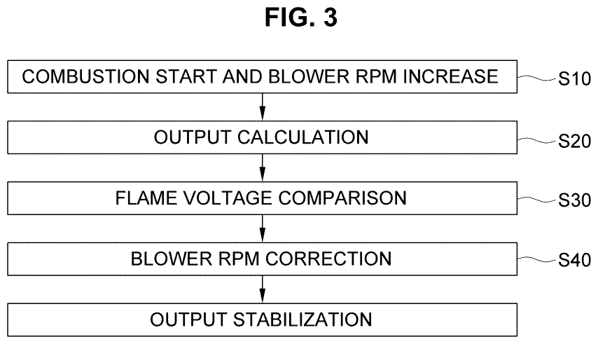

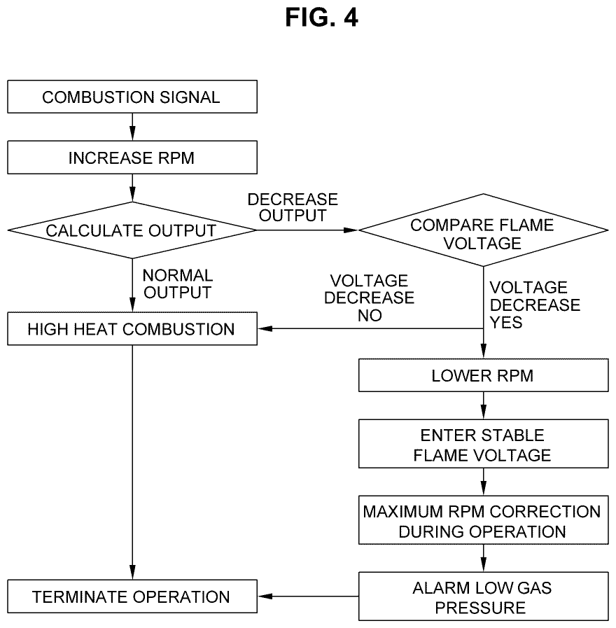

FIG. 3 is a process diagram illustrating a process of controlling operation according to the low gas pressure detection and compensation operation method of a gas water heater according to one embodiment of the present disclosure, and FIG. 4 is a flowchart illustrating a process for controlling operation according to the low gas pressure detection and compensation operation method of a gas water heater according to one embodiment of the present disclosure.

The low gas pressure detection and compensation operation method of a gas water heater according to one embodiment of the present disclosure includes a combustion start and blower RPM increase step (S10), an output calculation step (S20), a flame voltage comparison step (S30), and a blower RPM correction step (S40).

The combustion start and blower RPM increase stage (S10) is the initial operation stage of the boiler, and in this stage, output is generated along with combustion start and RPM of a blower increases.

In the output calculation step (S20), a control unit may calculate the output using the combustion temperature detected by the temperature sensor. The gas pressure supplied to the gas water heater cannot be maintained constant and may fluctuate, and when the gas pressure fluctuates, the output may also fluctuate. Therefore, in the output calculation step (S20), the output is calculated in real time.

When the output calculated in the output calculation step (S20) is determined to be normal, the high-heat combustion process may continue for a predetermined time and then the operation may be terminated normally. When the output calculated in the output calculation step (S20) is determined to be less than normal, compensation operation can be performed to normalize the output.

In the flame voltage comparison step (S30), when the output calculated in the output calculation step (S20) is determined to be less than normal, the current flame voltage is compared with the reference voltage. In other words, the state of the flame is determined based on whether or not the flame voltage fluctuates.

When it is determined that there is no decrease in flame voltage, the high-heat combustion process can continue for a predetermined time as when the output is normal, and then the operation may be terminated normally. That is, even when the calculated output has decreased, in a case where the flame condition is normal (no decrease in flame voltage), the gas pressure is determined to be normal, and normal operation is continued.

When it is determined that there is a decrease in flame voltage, that is, when it is determined that the supplied gas pressure is low, a process of correcting the output is performed.

In the blower RPM correction step (S40), when the flame voltage is determined to have decreased in the flame voltage comparison step (S30), the RPM of the blower is lowered. This allows the amount of air supplied to be reduced. When the amount of air supplied in a low gas pressure state is reduced, the air ratio (actual air value/theoretical air value) is maintained constant, and the flame remains stable, so the flame voltage enters the stabilization phase. The output decreases. In addition, the maximum RPM of the blower during operation is corrected in this step.

When it is determined that the gas pressure is low through output calculation using a temperature sensor and flame voltage comparison, an alarm is continuously displayed so that the user can check that the gas pressure is low during the process of low gas pressure. Through this alarm signal, the user can prevent accidents by checking whether gas leaks occur in pipes, or the like.

Even under low gas pressure conditions, when operation is continued with an appropriate air ratio, flame extinguishment can be prevented during combustion and CO generation can be suppressed. When additional combustion is not necessary, operation is terminated.

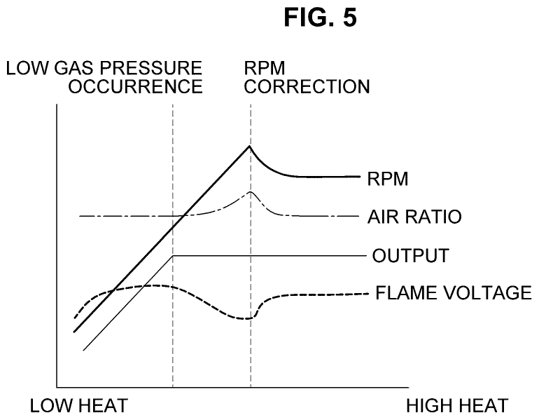

FIG. 5 is a graph illustrating operation according to the low gas pressure detection and compensation operation method of a gas water heater according to one embodiment of the present disclosure when a low gas pressure condition occurs after boiler operation.

When the boiler is started, the RPM of the blower increases and the output increases. The air ratio remains constant and the flame voltage gradually increases.

In a case where low gas pressure occurs during the boiler operation, even when the RPM of the blower increases, the increase in output is limited by the low gas pressure and the air ratio deviates from the normal value. As a result, the flame voltage drops. When the flame voltage drops below the standard value, the RPM increase of the blower is limited and instead decreases to maintain the air ratio constant. Accordingly, the flame voltage rises again and is maintained.

That is, after the RPM of the blower is corrected after the occurrence of low gas pressure, the RPM of the blower decreases and then remains constant, the air ratio remains constant at the normal value, and the output also remains constant. The flame voltage also rebounds and increases at the RPM correction point and then remains constant.

In this way, by correcting the RPM of the blower after the low gas pressure is generated, it can be confirmed that the air ratio, output, and flame voltage are maintained stably. This illustrates that combustion stability is maintained.

According to the present disclosure, when the gas supplied to the boiler suddenly enters a low gas pressure state during boiler operation, the air ratio can be maintained at a normal value by correcting the RPM of the blower by considering not only the output fluctuation but also the flame voltage fluctuation.

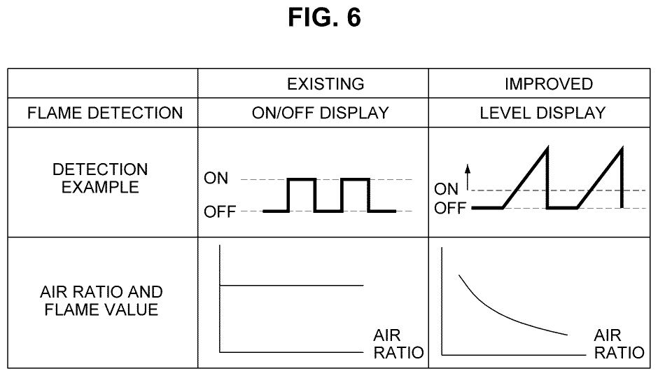

FIG. 6 is a graph comparing a flame detection method applied to the low gas pressure detection and compensation operation method of a gas water heater according to one embodiment of the present disclosure with a conventional flame detection method.

In conventional flame detection methods, flame detection is determined only in the form of on/off, so it is impossible to know whether the flame state changes, even when a change in the air ratio occurs. Meanwhile, in the case of determining the flame state using voltage change as in the present disclosure, the air ratio change and flame change can be easily observed through voltage fluctuations (for example, 0 to 4.5 V) that occur depending on the flame state.

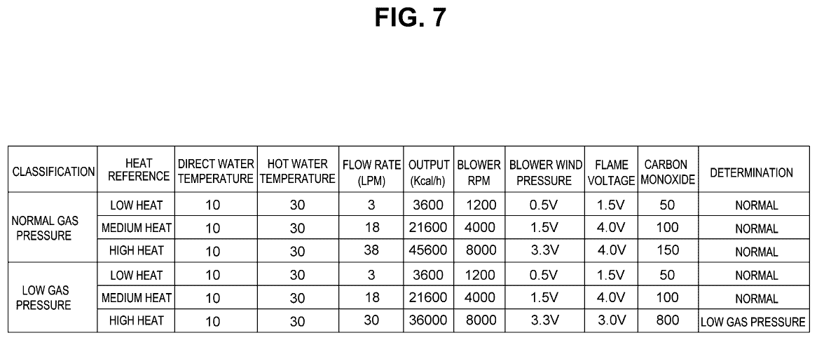

FIG. 7 is a table illustrating an example of operation under normal gas pressure and low gas pressure conditions.

Combustion air ratio and output changes can be detected using the measurement values (direct water temperature and hot water temperature) measured by the temperature sensor during operation, flow rate, flame voltage, blower RPM, and wind pressure information.

For example, looking at FIG. 7, in the case of low gas pressure, various pieces of information in a low heat section and a medium heat section are consistent with those in the low heat section and medium heat section of normal gas pressure, so it can be determined that operation is being performed normally.

On the other hand, in the high heat section, the output becomes smaller than that of the normal gas pressure (45,600 kcal/h->36,000 kcal/h), the flame voltage also decreases (4.0 V->3.0 V), and carbon monoxide increases rapidly (150->800), so it can be determined that the state is a low gas pressure state.

Although the low gas pressure detection and compensation operation method of a gas water heater according to a preferred embodiment of the present disclosure has been described in detail with reference to the attached drawings, the present disclosure is not limited to the above-described embodiment and may be implemented in various modified forms within the scope of the patent claims.

### Detailed Description of Main Elements

S10: combustion start and blower RPM increase step
S20: output calculation step
S30: flame voltage comparison step
S40: blower RPM correction step

What is claimed is:

1. A low gas pressure detection and compensation operation method of a gas water heater, the method comprising:
an output calculation step of calculating combustion output through combustion temperature detected by a temperature sensor and comparing the calculated output with a reference output;
a flame voltage comparison step of detecting flame voltage and comparing the detected flame voltage with a reference flame voltage when the calculated output is smaller than the reference output; and
a correction step of adjusting a supply air amount when the detected flame voltage is smaller than the reference flame voltage.

2. The method of claim 1, wherein it is determined that a supply gas pressure is in a low gas pressure state smaller than a reference value when the calculated output is smaller than the reference output and a current flame voltage is smaller than the reference flame voltage.

3. The method of claim 2, wherein when the supply gas pressure is determined to be in the low gas pressure state, in the correction step, the supply air amount is adjusted by adjusting the RPM of a blower to maintain an air ratio (actual air value/theoretical air value) within a normal range.

4. The method of claim 3, wherein an alarm is displayed to a user when the supply gas is in the low gas pressure state.

5. The method of claim 3, wherein a temperature sensor measurement value, a flame detection voltage, the RPM of the blower, and wind pressure information of the blower are considered in a process of checking the low gas pressure state of the supply gas and controlling the supply air amount.

6. The method of claim 5, wherein an amount of carbon monoxide (CO) generated in is additionally considered in the process of checking the low gas pressure state of the supply gas and controlling the supply air amount.

7. The method of claim 1, wherein an operation is terminated normally after high-heat combustion continues for a predetermined period of time when the output calculated in the output calculation step is determined to be normal.

8. The method of claim 1, wherein an operation is normally terminated after high-heat combustion continues for a predetermined period of time when it is determined that there is no decrease in flame voltage.

9. The method of claim 3, wherein in the correction step, the RPM of the blower is lowered to reduce the amount of air supplied, thereby maintaining the air ratio within a normal range.

10. The method of claim 9, wherein a maximum RPM of the blower is corrected in the correction step.

11. The method of claim 9, wherein when the RPM of the blower is corrected in the correction step, the RPM of the blower decreases and then remains constant, the air ratio is kept constant at a normal value, the output is also kept constant, and the flame voltage also rebounds and increases at an RPM correction point and then remains constant.

12. The method of claim 1, wherein the output is calculated in real time in the output calculation step.
